(19) United States
(12) Patent Application Publication
(10) Pub. No.: US 2018/0190823 A1
(43) Pub. Date: Jul. 5, 2018

(54) SEMICONDUCTOR DEVICE AND MANUFACTURING METHOD OF SEMICONDUCTOR DEVICE

(71) Applicant: Japan Display Inc., Tokyo (JP)

(72) Inventor: Hiroki OHARA, Tokyo (JP)

(21) Appl. No.: 15/844,690

(22) Filed: Dec. 18, 2017

(30) Foreign Application Priority Data
Jan. 4, 2017 (JP) 2017-000199

(51) Int. Cl. H01L 29/786; H01L 21/02; H01L 29/24; H01L 21/477; H01L 27/12

(52) U.S. Cl. CPC H01L 29/7869; H01L 21/02565; H01L 21/02631; H01L 27/1222; H01L 21/02126; H01L 21/477; H01L 29/24

(57) ABSTRACT

A manufacturing method of a semiconductor device includes forming an amorphous silicon film on an insulation surface, forming a silicon oxide film using an oxidation treatment from the amorphous silicon film, forming an oxide semiconductor layer above the silicon oxide film, forming a gate insulating film above the oxide semiconductor layer, and forming a gate electrode interposed by the gate insulating film above the oxide semiconductor layer.

### CROSS REFERENCE TO RELATED APPLICATIONS

This application is based upon and claims the benefit of priority from the prior Japanese Patent Application No. 2017-000199, filed on Jan. 4, 2017, the entire contents of which are incorporated herein by reference.

### FIELD

An embodiment of the present invention is related to a semiconductor device including an oxide semiconductor and a manufacturing method of the same

### BACKGROUND

Conventionally, a transistor using silicon as a semiconductor layer has been used in a display device such as a liquid crystal display device or an organic EL display device. In recent years, demands such as an increase in area, increasing resolution and increasing the frame rate in display devices and the like have been growing and efforts to satisfy these requirements have been actively carried out.

Therefore, recently, development of a transistor using an oxide semiconductor in place of silicon has been proceeding. It is expected that a transistor including an oxide semiconductor can realize high mobility. In particular, an oxide semiconductor layer using IGZO can be formed at a relatively low temperature and with a large area. As a result, oxide semiconductors have attracted attention as a material which satisfy the requirements described above (for example, Japanese Laid Open Patent Application Publication No. 2012-212714).

### SUMMARY

A manufacturing method of a semiconductor device includes forming an amorphous silicon film on an insulation surface, forming a silicon oxide film using an oxidation treatment from the amorphous silicon film, forming an oxide semiconductor layer above the silicon oxide film, forming a gate insulating film above the oxide semiconductor layer, and forming a gate electrode interposed by the gate insulating film above the oxide semiconductor layer.

A manufacturing method of a semiconductor device includes forming an amorphous silicon film on an insulation surface, forming a first region in which a part of the amorphous silicon film is oxidized using an oxidation treatment from a part of the amorphous silicon film, forming an oxide semiconductor layer above the first region, forming a gate insulating film above the oxide semiconductor layer, and forming a gate electrode interposed by the gate insulating film above the oxide semiconductor layer.

A semiconductor device includes an insulating layer above a substrate, an amorphous silicon film above the insulating layer, an oxide semiconductor layer above the amorphous silicon film, a gate insulating film above the oxide semiconductor layer, and a gate electrode arranged interposed by the gate insulating film above the oxide semiconductor layer, wherein the amorphous silicon has a first region on a side in contact with the insulating layer and a second region on a side in contact with the oxide semiconductor layer, an oxygen concentration of the first region is lower than an oxygen concentration of the second region.

### BRIEF DESCRIPTION OF DRAWINGS

FIG. 1 is a cross-sectional view of a semiconductor device related to one embodiment of the present invention;

FIG. 2A is a cross-sectional view of a manufacturing method of a semiconductor device related to one embodiment of the present invention;

FIG. 2B is a cross-sectional view of a manufacturing method of a semiconductor device related to one embodiment of the present invention;

FIG. 2C is a cross-sectional view of a manufacturing method of a semiconductor device related to one embodiment of the present invention;

FIG. 2D is a cross-sectional view of a manufacturing method of a semiconductor device related to one embodiment of the present invention;

FIG. 2E is a cross-sectional view of a manufacturing method of a semiconductor device related to one embodiment of the present invention;

FIG. 2F is a cross-sectional view of a manufacturing method of a semiconductor device related to one embodiment of the present invention;

FIG. 3 is a cross-sectional view of a semiconductor device related to one embodiment of the present invention;

FIG. 4 is a cross-sectional view of a semiconductor device related to one embodiment of the present invention;

FIG. 5 is a cross-sectional view of a semiconductor device related to one embodiment of the present invention;

FIG. 6 is a cross-sectional view of a semiconductor device related to one embodiment of the present invention;

FIG. 7A is a cross-sectional view of a manufacturing method of a semiconductor device related to one embodiment of the present invention;

FIG. 7B is a cross-sectional view of a manufacturing method of a semiconductor device related to one embodiment of the present invention;

FIG. 7C is a cross-sectional view of a manufacturing method of a semiconductor device related to one embodiment of the present invention;

FIG. 7D is a cross-sectional view of a manufacturing method of a semiconductor device related to one embodiment of the present invention;

FIG. 7E is a cross-sectional view of a manufacturing method of a semiconductor device related to one embodiment of the present invention;

FIG. 7F is a cross-sectional view of a manufacturing method of a semiconductor device related to one embodiment of the present invention;

FIG. 8 is a cross-sectional view of a semiconductor device related to one embodiment of the present invention;

FIG. 9 is a cross-sectional view of a semiconductor device related to one embodiment of the present invention;

FIG. 10 is a cross-sectional view of a semiconductor device related to one embodiment of the present invention;

FIG. 11 is a cross-sectional view of a semiconductor device related to one embodiment of the present invention;

FIG. 12 is a cross-sectional view of a display device related to one embodiment of the present invention;

FIG. 13 is a cross-sectional view of a display device related to one embodiment of the present invention; and

FIG. 14 is a cross-sectional view of a semiconductor device related to one embodiment of the present invention.

### DESCRIPTION OF EMBODIMENTS

Each embodiment of the present invention is explained below while referring to the diagrams. However, the present invention can be carried out using various forms within a scope that does not depart from the concept of the present invention and should not be interpreted as being limited to the description details of the embodiments exemplified herein.

Although the width, thickness and shape of each component are shown schematically compared to their actual form in order to better clarify explanation, the drawings are merely an example and should not limit an interpretation of the present invention. In the specification and each drawing, the same reference symbols are attached to similar elements and elements that have been mentioned in previous drawings, and therefore a repeated explanation may be omitted where appropriate.

In an embodiment of the present invention, in the case where a plurality of films is formed by processing a one certain film, this plurality of films may sometimes have different functions or roles. However, this plurality of films is derived from a film formed from the same layer using the same process and has the same layer structure and same material. Therefore, this plurality of films is defined as existing in the same layer.

In the present specification and the scope of the patent claims, when expressing a mode in which another structure is arranged above a certain structure, in the case where it is simply described as “above”, unless otherwise noted, a case where another structure is arranged directly above a certain structure as if in contact with that structure, and a case where another structure is arranged via another structure above a certain structure, are both included.

### First Embodiment

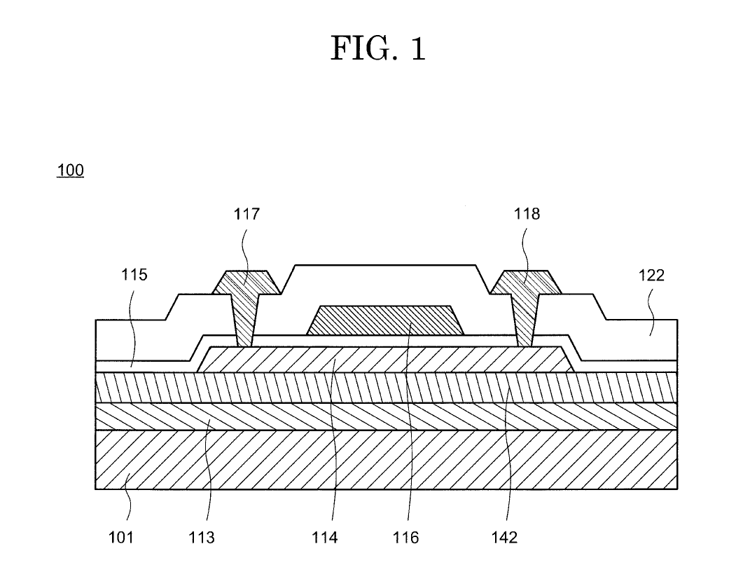

In the present embodiment, a semiconductor device according to one embodiment of the present invention is explained while referring to FIG. 1 to FIG. 5. In the present embodiment, the structure of a top-gate transistor is explained.

### <Structure of Semiconductor Device>

A summary of a semiconductor device 100 according to the first embodiment of the present invention is explained while referring to FIG. 1.

FIG. 1 is a cross-sectional view of a semiconductor device 100 according to the present embodiment. The semiconductor device 100 includes a substrate 101, an insulating layer 113, an insulating layer 142, an oxide semiconductor layer 114, an insulating layer 115, a conducting layer 116, an insulating layer 122, a conducting layer 117 and a conducting layer 118.

A glass substrate, quartz substrate, flexible substrate (polyimide, polyethylene terephthalate, polyethylene naphthalate, triacetyl cellulose, cyclic olefin copolymer, cycloolefin polymer, other resin substrates having flexibility) can be used as the substrate 101. In the case when it is not necessary that the substrate 101 has translucency, it is also possible to use a metal substrate, ceramic substrate, or a semiconductor substrate.

The insulating layer 113 functions as an under layer. The insulating layer 113 is a film having a function of preventing impurities such as alkali metal from diffusing into the oxide semiconductor layer 114 and the like, and functions as a barrier film. Silicon nitride (SiNx), silicon nitride oxide (SiNxOy), aluminum nitride (AlNx), aluminum nitride oxide (AlNxOy), aluminum oxide (AlOx), aluminum oxynitride (AlOxNy), or the like can be used as the insulating layer 113, (x and y are arbitrary). In addition, the insulating layer 113 may have a structure in which these films are stacked. Furthermore, the amount of hydrogen contained in the insulating layer 113 is preferably low.

In a transistor which uses an oxide semiconductor layer, carriers are generated when hydrogen is mixed in the oxide semiconductor layer. When carriers are generated in the oxide semiconductor layer, a threshold voltage are shifted, transistor characteristics deteriorate which cause the reliability of the semiconductor device using the transistor to decrease. Therefore, it is effective to use a film having a low hydrogen concentration as an insulating layer in contact with the oxide semiconductor layer 114.

In order to form an insulating layer (for example, silicon oxide) having a low hydrogen concentration, it is preferable to form the insulating layer by a sputtering method. However, in the case of manufacturing a semiconductor device with a large substrate, it is technically difficult to form a film by a sputtering method, and the manufacture of the target itself has not been established. In addition, in the case when silicon oxide is formed by a plasma CVD (Chemical Vapor Deposition) method, the hydrogen concentration becomes high because SiH₄ and N₂O are used as a reaction gas. The concentration of hydrogen included in a silicon oxide film formed by a plasma CVD method is, for example, 5×10²² to 1×10²³ atom/cm³. In addition, in order to reduce the hydrogen concentration, even if the flow rate of the SiH₄ gas is reduced and the flow rate of the N₂O gas is increased, the hydrogen concentration included in the silicon oxide film is, for example, 1×10²² to 5×10²² atoms/cm³.

In the present embodiment, an insulating film such as a silicon oxide film is not formed by a plasma CVD method but an insulating film is formed by oxidizing a silicon film with a low hydrogen concentration. For example, a silicon oxide film formed by subjecting an amorphous silicon film to an oxidation treatment is used as the insulating layer 142. According to this method, even when an amorphous silicon film is a film formed by a plasma CVD method, it is possible to reduce the hydrogen concentration compared with a silicon oxide film or silicon nitride film formed by a plasma CVD method. The concentration of hydrogen included in amorphous silicon formed by a plasma CVD method is, for example, 1×10²¹ to 5×10²¹ atoms/cm³. Therefore, by subjecting an amorphous silicon film with a low hydrogen concentration to an oxidation treatment, it is possible to form a silicon oxide film having a low hydrogen concentration. In addition, productivity is increased compared with that of a silicon oxide film formed by a sputtering method. Although amorphous silicon is exemplified in the present embodiment, the present invention is not limited to amorphous silicon, and as long as it is a silicon film in which the hydrogen concentration within the film is reduced to approximately 1×10²¹ to 5×10²¹ atoms/cm³, it can be similarly applied even if it is not silicon with an amorphous form.

The oxide semiconductor layer 114 can include a group 13 element such as indium or gallium. The oxide semiconductor layer 114 may also include contain a plurality of different group 13 elements or a compound of indium and gallium (IGO). The oxide semiconductor layer 114 may further include a group 12 element, for example a compound including indium, gallium, and zinc (IGZO). The oxide semiconductor layer 114 can include other elements and may include tin which is a group 14 element and titanium or zirconium which are group 4 elements. The crystallinity of the oxide semiconductor layer 114 is also not limited and may be single crystal, polycrystal, microcrystal or amorphous. The oxide semiconductor layer 114 is preferred to have few crystal defects such as oxygen defects. In addition, it is preferred that the concentration of hydrogen in the oxide semiconductor layer 114 is low.

The insulating layer 115 functions as a gate insulating film. Silicon nitride (SiNx), silicon nitride oxide (SiNxOy), silicon oxide (SiOx), silicon oxynitride (SiOxNy), aluminum nitride (AlNx), aluminum nitride oxide (AlNxOy), aluminum oxide (AlOx), aluminum oxynitride (AlOxNy) or the like can be used for the insulating layer 115 (x and y are arbitrary). In addition, the insulating layer 115 may have a structure in which these films are stacked. Furthermore, the amount of hydrogen included in the insulating layer 115 is preferred to be low.

The conducting layer 116 functions as a gate electrode. Aluminum (Al), titanium (Ti), chromium (Cr), cobalt (Co), nickel (Ni), zinc (Zn), molybdenum (Mo), copper (Cu), tin (Sn), hafnium (Hf), tantalum (Ta), tungsten (W), platinum (Pt), bismuth (Bi) and the like can be used for the conducting layer 116. In addition, alloys of these metals may also be used. In addition, conductive oxides such as ITO (indium tin oxide), IGO (indium gallium oxide), IZO (indium zinc oxide), and GZO (zinc oxide doped with gallium as a dopant) may also be used. In addition, a structure in which these films are stacked may also be used.

The insulating layer 122 functions as an interlayer insulating film. The same material as the insulating layer 115 can be used for the insulating layer 122. In addition, the insulating layer 122 may have a single layer structure or a stacked layer structure.

The conducting layer 117 and the conducting layer 118 function as a source electrode or a drain electrode. The same material as the conducting layer 116 can be used for the conducting layer 117 and the conducting layer 118. In addition, the conducting layer 117 and the conducting layer 118 may have a single layer structure or a stacked structure.

In the semiconductor device 100 described in the present embodiment, a film with a reduced hydrogen concentration is used as the insulating layer 142 which is in contact with the oxide semiconductor layer 114. In this way, it is possible to suppress hydrogen, which causes carriers to be generated in the oxide semiconductor layer 114, from entering into the oxide semiconductor layer 114. Therefore, since it is possible to suppress a shift of the threshold voltage of a transistor and deterioration of transistor characteristics, it is possible to improve reliability of the semiconductor device using the transistor.

Furthermore, in addition to the transistor shown in FIG. 1, a top-gate transistor having a self-aligned structure may also be used. Self-alignment means to use an already formed pattern as a mask in the subsequent process and proceed with the subsequent process without mask alignment. In addition, the case where an initial pattern or shape determines the shape of the final transistor is also called self-alignment. In the present embodiment, it is possible to form a transistor with a self-aligned structure by selectively reducing the resistance of the oxide semiconductor layer 114 using the conducting layer 116 which acts as a gate electrode as a mask.

### <Method of Manufacturing Semiconductor Device>

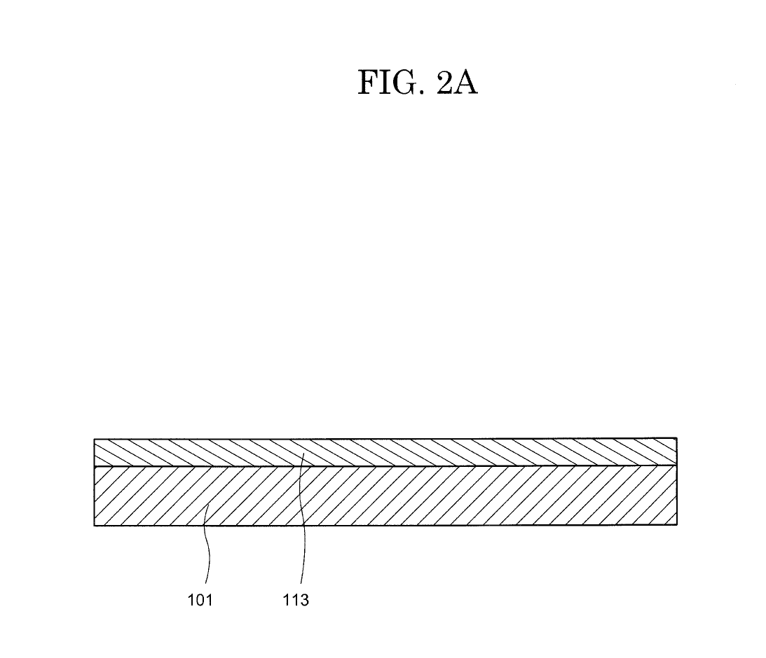

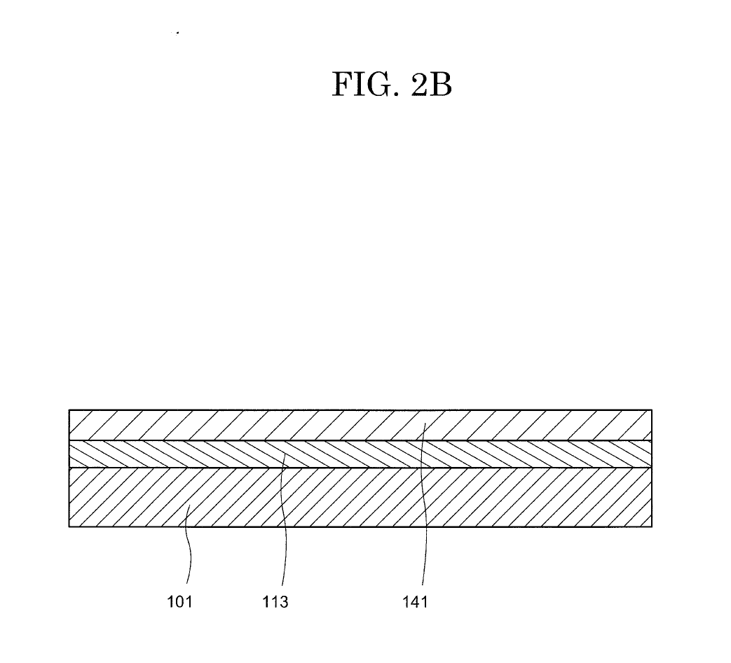

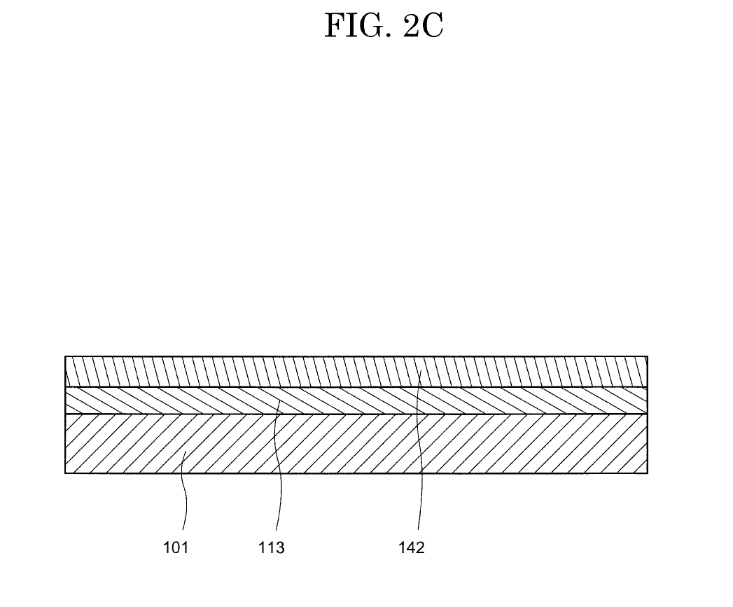

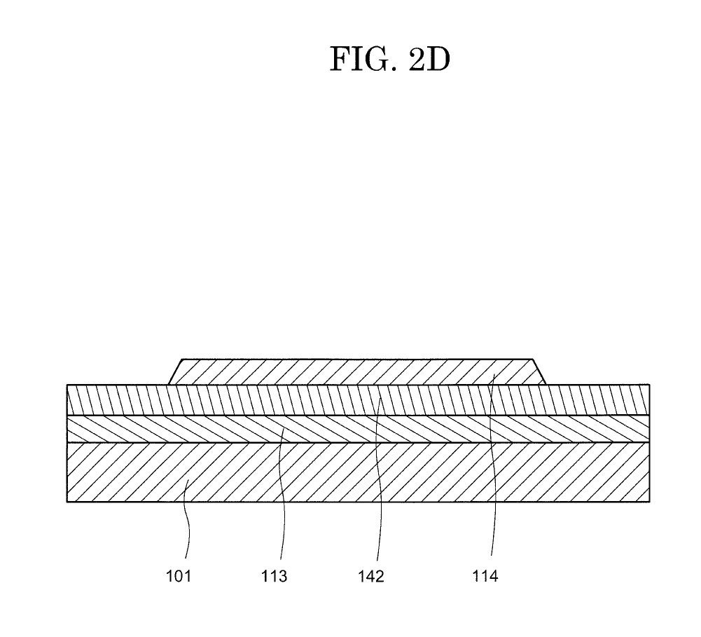

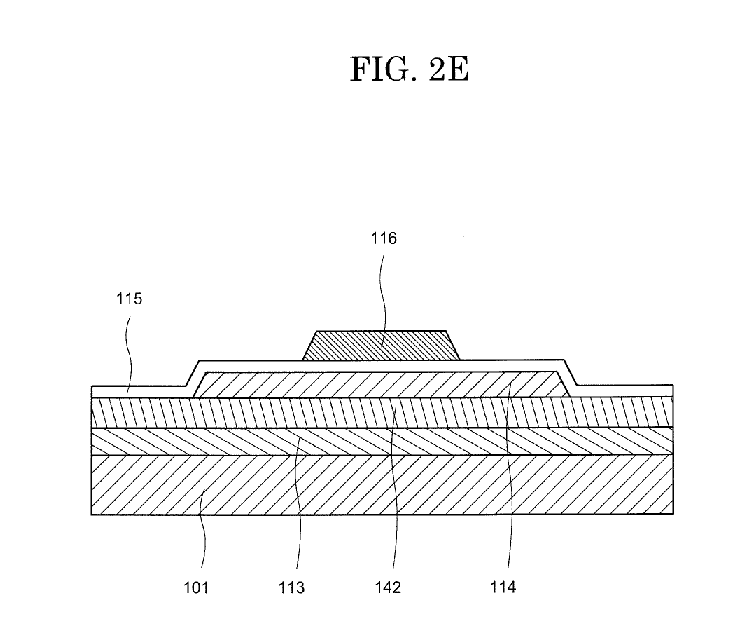

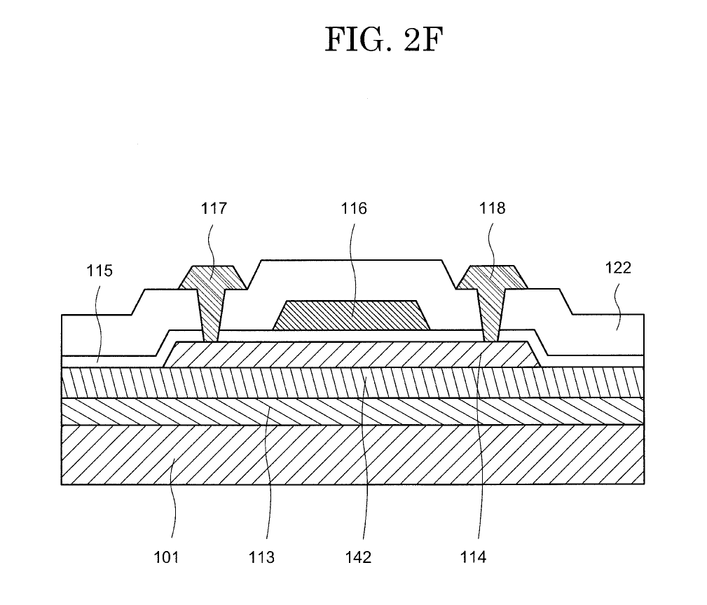

A method of manufacturing the semiconductor device 100 according to the present embodiment is explained while referring to FIG. 2A to FIG. 2F.

First, as shown in FIG. 2A, an insulating layer 113 is formed above a substrate 101. The insulating layer 113 can be formed having a single layer structure or a stacked structure by using the materials described previously by a CVD method, a sputtering method, or a lamination method and the like. The film thickness of the insulating layer 113 is set to 50 nm or more and 1000 nm or less.

Next, as shown in FIG. 2B, an amorphous silicon film 141 is formed above the insulating layer 113. The amorphous silicon film 141 can be formed by a plasma CVD method using SiH₄ gas. In addition, the film thickness of the amorphous silicon film 141 is preferably set to 60 nm or more and 250 nm or less. Furthermore, if the film quality of the amorphous silicon film 141 is sparse, it can be thickened, and easily oxidized in a subsequent oxidation treatment.

Next, as shown in FIG. 2C, the insulating layer 142 is formed by performing an oxidation treatment on the amorphous silicon film 141. A plasma treatment or thermal treatment can be performed as the oxidation treatment. When a plasma treatment is performed on the amorphous silicon film 141, it can be performed under an atmospheric pressure plasma or low pressure (vacuum) using a gas including oxygen such as O₂, N₂O, or O₂/N₂. Pressure, gas flow rate, power and treatment time and the like may be set to conditions for easy oxidation according to the film quality and film thickness of the amorphous silicon film 141. Furthermore, in the case of performing a plasma treatment, the plasma CVD device in which the amorphous silicon film 141 is formed can be continuously used. Therefore, it is preferred since a separate device is not necessary which increases productivity.

In addition, when a thermal treatment is performed on the amorphous silicon film 141, it can be performed at an atmospheric pressure or low pressure (vacuum) using a gas including oxygen such as O₂, N₂O, or O₂/N₂. The pressure, gas flow rate, heating temperature and the treatment time and the like may be set to conditions at which oxidization is easy according to the film quality and film thickness of the amorphous silicon film 141. In addition, the heating temperature can be set to 100° C. or more and 600° C. or less. Furthermore, in the case where a plastic substrate is used as the substrate 101, it is preferred to perform heating at a temperature of 100° C. or more and 450° C. or less.

By performing an oxidation treatment on the amorphous silicon film 141 having a low hydrogen concentration, it is possible to form the insulating layer 142 with a reduced hydrogen concentration. By forming the oxide semiconductor layer 114 above the insulating layer 142, it is possible to suppress hydrogen from entering the oxide semiconductor layer 114 from the insulating layer 142 in a subsequent manufacturing process.

Next, as shown in FIG. 2D, the oxide semiconductor layer 114 is formed above the insulating layer 142. The oxide semiconductor layer 114 is formed by processing the oxide semiconductor film into a desired shape by performing patterning after forming the oxide semiconductor film. It is preferred that the oxide semiconductor film is formed with a thickness of 30 nm or more and 100 nm or less by a sputtering method for example. In the case when a sputtering method is used, formation of the oxide semiconductor film is performed by heating the substrate in an atmosphere including oxygen gas, for example, a mixed atmosphere including argon and oxygen. At this time, partial pressure of argon may be set lower than the partial pressure of oxygen.

In addition, a power supply to be applied to the target may be a direct current power supply or an alternating current power supply and can be determined by the shape and composition of the target. For example, in the case of InGaZnO, In:Ga:Zn:O=1:1:1:4 (In₂O₃:Ga₂O₃:ZnO=1:1:2) or the like can be used as the target. In addition, the composition ratio can be determined according to the purpose such as the characteristics of the transistor.

In addition, a thermal treatment may be performed on the oxide semiconductor layer 114. The thermal treatment may be performed before or after patterning of the oxide semiconductor film. Since the volume of the oxide semiconductor layer 114 may be reduced (shrinked) by a thermal treatment, it is preferred that the thermal treatment is performed before patterning. In addition, by performing a thermal treatment on the oxide semiconductor layer 114, it is possible to improve film quality such as a reduction in hydrogen concentration and density improvement of the oxide semiconductor layer 114.

A thermal treatment performed on the oxide semiconductor layer 114 can be performed under atmospheric pressure or low pressure (vacuum) in the presence of nitrogen, dry air or air. The thermal treatment temperature is 250° C. to 500° C., preferably 350° C. to 450° C. In addition, the thermal treatment time is 15 minutes to 1 hour for example. By performing a thermal treatment, oxygen is introduced or transferred into oxygen defects in the oxide semiconductor layer 114, thereby it is possible to obtain the oxide semiconductor layer 114 having few crystal defects and high crystallinity. In addition, by performing a thermal treatment, it is possible to reduce the hydrogen concentration of the oxide semiconductor layer 114.

Furthermore, a plasma treatment may be performed on the oxide semiconductor layer 114. The plasma treatment can be carried out at atmospheric pressure plasma or low pressure (vacuum) using O₂ gas or N₂O gas. By performing a plasma treatment on the oxide semiconductor layer 114, it is possible to reduce for oxygen defects in the oxide semiconductor layer 114. In this way, the characteristics and reliability of the transistor are improved.

Next, as shown in FIG. 2E, an insulating layer 115 is formed above the oxide semiconductor layer 114. The insulating layer 115 can be formed having a single layer structure or a stacked structure using the materials described above by a CVD method or a sputtering method and the like. In addition, the thickness of the insulating layer 115 can be set to 50 nm or more and 500 nm or less. It is preferred that the concentration of hydrogen included in the insulating layer 115 is low.

Next, a conducting layer 116 is formed above the insulating layer 115. The conducting layer 116 is formed by forming a conductive film, performing patterning and processing the film into a desired shape. The conducting film can be formed in a single layer structure or a laminated structure by a sputtering method using the materials described above. For example, MoW is used to form the conducting layer 116. In addition, the thickness of the conducting layer 116 can be set to 200 nm or more and 500 nm or less.

Next, impurities are added to the oxide semiconductor layer 114 via the insulating layer 215 using the conducting layer 116 as a mask. Impurities such as B, P, N₂ or H₂ are added to the oxide semiconductor layer 114 by using an ion implantation method. In the region of the oxide semiconductor layer 114 doped with the impurities, oxygen defects occur and oxygen moves which improve conductivity. Furthermore, the resistance value of the region to which the impurity is added is appropriately adjusted by the dose amount of impurities. In the oxide semiconductor layer 114, a region to which impurities are added functions as a source region or a drain region.

In addition to the ion implantation method, a plasma treatment may be performed as a method of adding impurities to the oxide semiconductor layer 114. The plasma treatment can be carried out at atmospheric pressure plasma or low pressure (vacuum) using H₂, N₂, SiH₂ or H₂O gas. By performing a plasma treatment on the oxide semiconductor layer 114, a connection between the source region or the drain region and the conducting layer 117 which functions as a source electrode and the conducting layer 118 which functions as a drain electrode can be improved.

Next, as shown in FIG. 2F, the insulating layer 122 is formed above the insulating layer 115 and the conducting layer 116. The insulating layer 122 can be formed having a single layer structure or a stacked structure using the materials described above or an organic insulating material such as a polyimide resin, an acrylic resin, an epoxy resin, a silicone resin, a fluorine resin, or a siloxane resin by a CVD method or a sputtering method. In addition, the thickness of the insulating layer 122 can be set to 200 nm or more and 1000 nm or less.

Next, an opening is formed in the insulating layer 122 to expose the oxide semiconductor layer 114. Following this, the conducting layer 117 and the conducting layer 118 which are connected to the oxide semiconductor layer 114 are formed. The conducting layer 117 and the conducting layer 118 are formed by forming a conducting film above the insulating layer 122 and subsequently processing into a desired shape by patterning the conducting film. The conducting film can be formed in a single layer structure or a stacked structure by a sputtering method using the materials described above. In the case of forming the conducting layer 117 and the conducting layer 118 with a stacked structure, Ti, Al, and Ti are formed in this order above the insulating layer 122. In addition, the thickness of the conducting layer 117 and the conducting layer 118 can be set to 300 nm or more and 800 nm or less.

The semiconductor device 100 can be manufactured by the processes described above. According to the manufacturing method of the semiconductor device according to the present embodiment, the insulating layer 142 having a reduced hydrogen concentration can be formed by forming the amorphous silicon film 141 above the insulating layer 113 and performing an oxidation treatment. By forming the oxide semiconductor layer 114 above the insulating layer 142 which has a reduced hydrogen concentration, it is possible to reduce hydrogen which causes carriers to be generated in the oxide semiconductor layer 114. In this way, since it is possible to suppress a shift of the threshold voltage of the transistor and degradation of transistor characteristics, it is possible to improve the reliability of the semiconductor device using the transistor.

In addition, in the case of forming a self-aligned transistor, in the process shown in FIG. 2E, by performing ion implantation or a plasma treatment using the conducting layer 116 which functions as a gate electrode as a mask, oxygen defects are generated in the oxide semiconductor layer 114. In this way, it is possible to form a source region and a drain region in the oxide semiconductor layer 114. Alternatively, using the conducting layer 116 which functions as a gate electrode as a mask, the insulating layer 115 which functions as a gate insulating film is removed to expose the oxide semiconductor layer 114. Following this, by using the conducting layer 116 as a mask, by performing ion implantation or a plasma treatment on the oxide semiconductor layer 114, the resistance of the oxide semiconductor layer 114 may be lowered and the source region and the drain region may be formed.

### Modified Example 1

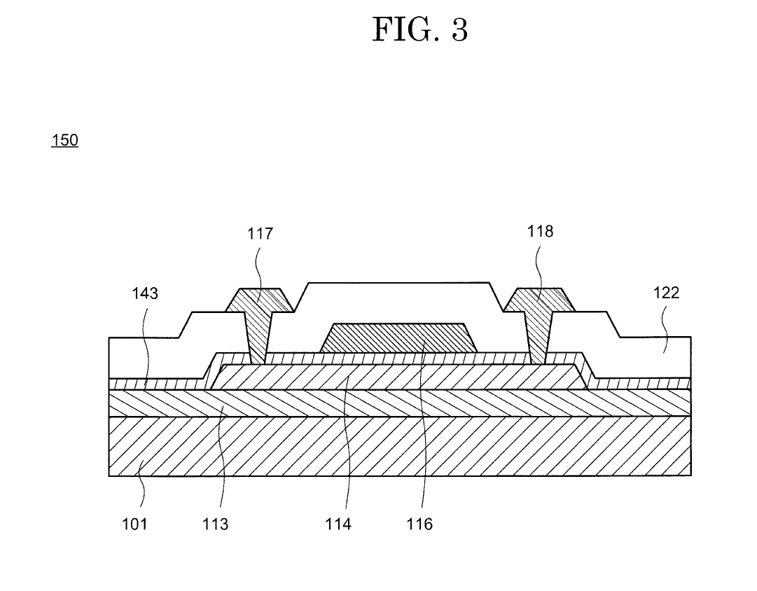

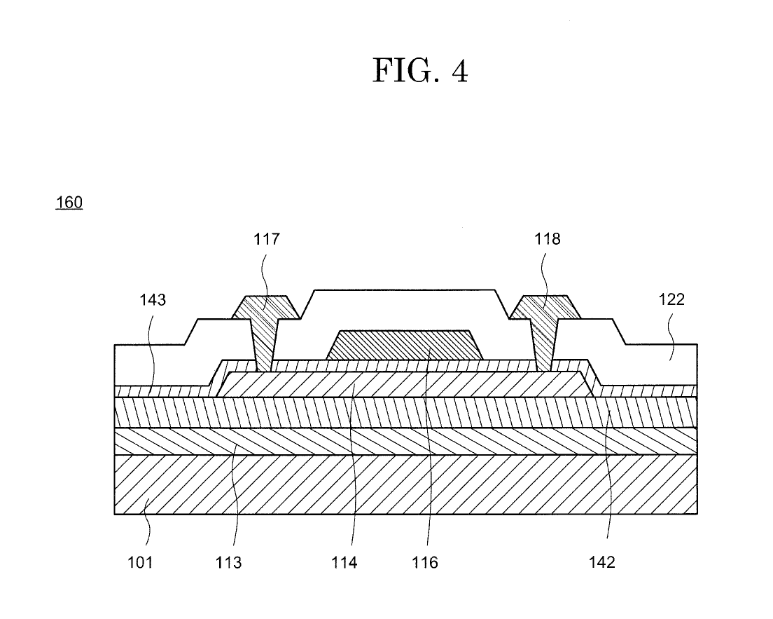

Next, a semiconductor device having a partly different structure from the semiconductor device shown in FIG. 1 is explained while referring to FIG. 3 and FIG. 4.

In the semiconductor device 150 shown in FIG. 3, the oxide semiconductor layer 114 is arranged above the insulating layer 113, and an insulating layer with a reduced hydrogen concentration is used for the insulating layer 143 in contact with the oxide semiconductor layer 114. The insulating layer 143 functions as a gate insulating film. The insulating layer 143 can be formed by oxidizing an amorphous silicon film. Since the other structures are similar to the semiconductor device 100 shown in FIG. 1, a detailed explanation is omitted.

A plasma treatment or thermal treatment can be performed as the oxidation treatment of the amorphous silicon film. In the case of a plasma treatment, it can be performed at an atmospheric pressure or low pressure (vacuum) using a gas including oxygen such as O₂, N₂O, or O₂/N₂. It is possible to set conditions such as pressure, gas flow rate, power, and processing time and the like so that oxidation easily occurs according to the film quality and film thickness of the amorphous silicon film.

In addition, when a thermal treatment is performed on the amorphous silicon film, it can be performed at an atmospheric pressure plasma or low pressure (vacuum) by using a gas including oxygen such as O₂, N₂O or O₂/N₂. It is possible to set conditions such as pressure, gas flow rate, power, and processing time and the like so that oxidation easily occurs according to the film quality and film thickness of the amorphous silicon film. Furthermore, the heating temperature is preferably 450° C. or lower in consideration of heat resistance of the oxide semiconductor layer 114.

In the semiconductor device 150 shown in FIG. 3, a film having a reduced hydrogen concentration is used as the insulating layer 143 in contact with the oxide semiconductor layer 114. In this way, it is possible to suppress the entry of hydrogen which causes carriers to be generated in the oxide semiconductor layer 114, into the oxide semiconductor layer 114. Therefore, it is possible to suppress a shift of the threshold voltage of the transistor and it is possible to improve the reliability of the semiconductor device using the transistor.

In the semiconductor device 160 shown in FIG. 4, an insulating layer with a reduced hydrogen concentration is used for the insulating layer 142 and the insulating layer 143 which are in contact with the oxide semiconductor layer 114. Each of the insulating layer 142 and the insulating layer 143 can be formed by oxidizing the amorphous silicon film. Since the other structures are similar to the semiconductor device 100 shown in FIG. 1, a detailed explanation is omitted.

In addition, since the method of forming the insulating layer 142 and the insulating layer 143 is similar to the method explained in FIG. 1 to FIG. 3, a detailed explanation is omitted.

In the semiconductor device 160 illustrated in FIG. 4, an insulating layer with a reduced hydrogen concentration is used for the insulating layer 142 and the insulating layer 143 which are in contact with the oxide semiconductor layer 114. In this way, it is possible to suppress hydrogen which causes carriers to be generated in the oxide semiconductor layer 114, from entering the oxide semiconductor layer 114 more than the semiconductor devices shown in FIG. 1 and FIG. 3. Therefore, since it is possible to suppress a shift of the threshold voltage of the transistor and deterioration of transistor characteristics, it is possible to improve the reliability of the semiconductor device using the transistor.

### Modified Example 2

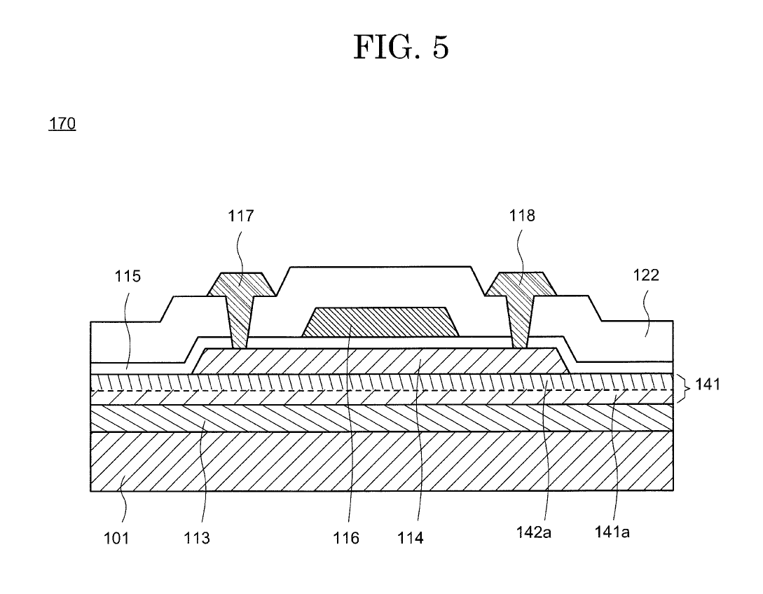

Next, a semiconductor device having a partly different structure from the semiconductor device shown in FIG. 1 is explained while referring to FIG. 5.

In the semiconductor device 170 shown in FIG. 5, a part of the amorphous silicon film 141 is oxidized. That is, the side in contact with the insulating layer 113 remains amorphous silicon, and the side in contact with the oxide semiconductor layer 114 is silicon oxide. Furthermore, the boundary between the amorphous silicon 141a and the oxidized region 142a is sometimes unclear. As a result, in FIG. 5, the boundary between the amorphous silicon 141a and the oxidized region 142a is shown by a dotted line. Since the other structures are similar to the semiconductor device 100 shown in FIG. 1, a detailed explanation is omitted.

By oxidizing a part of the amorphous silicon film 141, in the region in contact with the oxide semiconductor layer 114, it is possible to form the oxidized region 142a having a reduced hydrogen concentration. In addition, in the amorphous silicon film 141, the amorphous silicon 141a in contact with the insulating layer 113 has a lower oxidation concentration than the oxidized region 142a in contact with the oxide semiconductor layer 114. In addition, not all of the amorphous silicon film 141 is oxidized but a part of the amorphous silicon 141a remains in a region in contact with the insulating layer 113. Since it is possible to release an electric charge by the amorphous silicon 141a, it is possible to prevent static electricity breakage of a transistor due to electrostatic discharge (ESD: Electro Static Discharge).

In addition, in a transistor which includes an oxide semiconductor layer, when light irradiated from the rear surface side of the oxide semiconductor layer is incident on the oxide semiconductor layer, an off current increases which may deteriorate characteristics. By leaving a part of the amorphous silicon 141a in contact with the insulating layer 113, the amorphous silicon 141a can function as a light shielding film. In this way, even when light is irradiated from the rear surface side of the oxide semiconductor layer 114, it is possible to prevent light from entering the oxide semiconductor layer 114. In this way, it is possible to reduce the off current of the transistor and prevent degradation of transistor characteristics.

In addition, similar to the other semiconductor devices, it is possible to suppress a shift of the threshold voltage of the transistor and suppress deterioration of transistor characteristics. Therefore, it is possible to improve the reliability of the semiconductor device using the transistor.

In the semiconductor device 170 shown in FIG. 5, the film thickness of the amorphous silicon film 141 can be set to 60 nm or more and 250 nm or less. Within this range, the thickness of the amorphous silicon 141a is preferably 5 nm or more and 20 nm or less.

Furthermore, in the semiconductor device 170 shown in FIG. 5, it is possible to use an insulating layer 143 formed by oxidizing an amorphous silicon film instead of the insulating layer 115 which functions as a gate insulating film.

### Second Embodiment

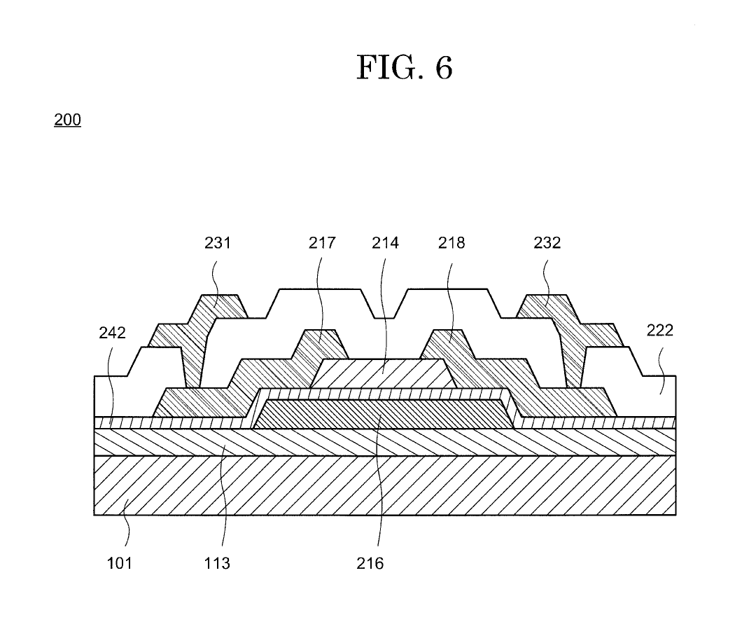

In the present embodiment, a semiconductor device according to one embodiment of the present invention is explained while referring to FIG. 6 to FIG. 9. In the present embodiment, the structure of a bottom-gate transistor is explained. Furthermore, in the case when the contents explained in the first embodiment overlap with the second embodiment, an explanation will be omitted as appropriate.

### <Structure of Semiconductor Device>

A cross-sectional view of a semiconductor device 200 according to the present embodiment is shown in FIG. 6. The semiconductor device 200 includes a substrate 101, an insulating layer 113, a conducting layer 216, an insulating layer 242, an oxide semiconductor layer 214, a conducting layer 217, a conducting layer 218, an insulating layer 222, a conducting layer 231, and a conducting layer 232.

The conducting layer 216 functions as a gate electrode. It is possible to use a material similar to that of the conducting layer 116 as the conducting layer 216. In addition, the conducting layer 116 may have a single layer structure or a stacked structure.

The insulating layer 242 functions as a gate insulating film. In the present embodiment, an insulating layer having a low hydrogen concentration is used as the insulating layer 242 which is in contact with the oxide semiconductor layer 214. In this way, it is possible to suppress entry of hydrogen which causes carriers to be generated in the oxide semiconductor layer 114, from entering into the oxide semiconductor layer 114. Therefore, since it is possible to suppress a shift of the threshold voltage of the transistor, it is possible to improve reliability of the semiconductor device using the transistor.

A silicon film having a low hydrogen concentration is formed as the insulating layer 242, for example, and subsequently an insulating film formed by performing an oxidation treatment is used. For example, a silicon oxide film formed by subjecting an amorphous silicon film to an oxidation treatment is used as the insulating layer 242.

A material similar to that of the oxide semiconductor layer 114 can be used for the oxide semiconductor layer 214. In addition, the conducting layer 217 and the conducting layer 218 function as a source electrode or a drain electrode. Materials similar to those of the conducting layer 117 and the conducting layer 118 can be used for the conducting layer 217 and the conducting layer 218. In addition, the conducting layer 217 and the conducting layer 218 may have a single layer structure or a stacked layer structure.

The insulating layer 222 functions as a protective film. The same material as the insulating layer 212 can be used for the insulating layer 222. In addition, the insulating layer 222 may have a single layer structure or a stacked layer structure.

The conducting layer 231 and the conducting layer 232 function as wiring. The conducting layer 231 and the conducting layer 232 are respectively connected to the conducting layer 217 and the conducting layer 218 through a plurality of openings formed in the insulating layer 222. The conducting layer 231 and the conducting layer 232 can be formed using the same materials as those of the conducting layers 217 and 218. In addition, the conducting layer 231 and the conducting layer 232 may have a single layer structure or a stacked structure.

### <Method of Manufacturing Semiconductor Device>

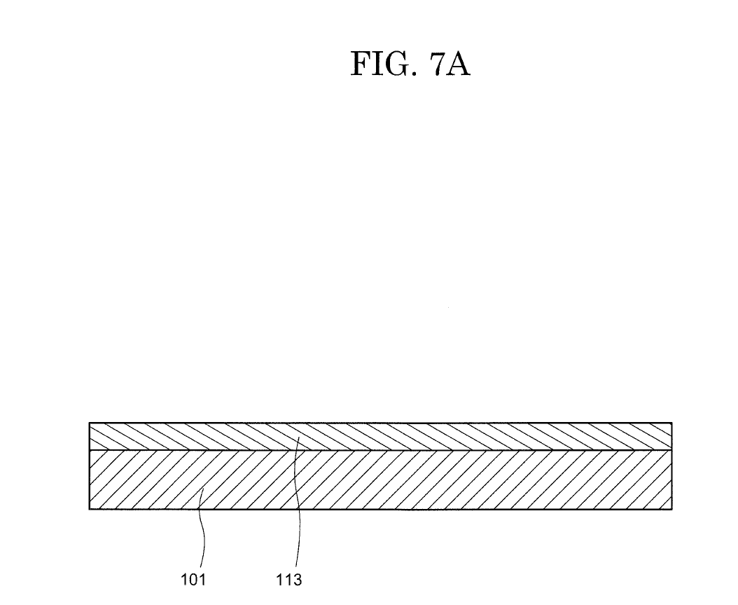

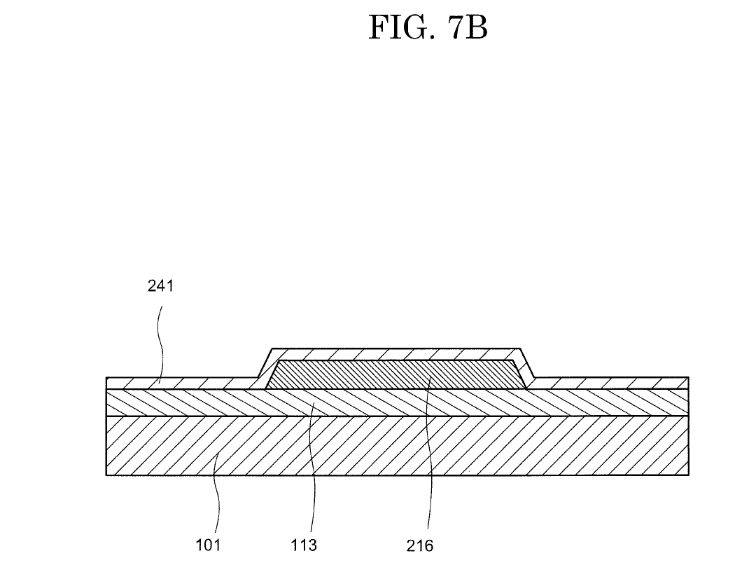

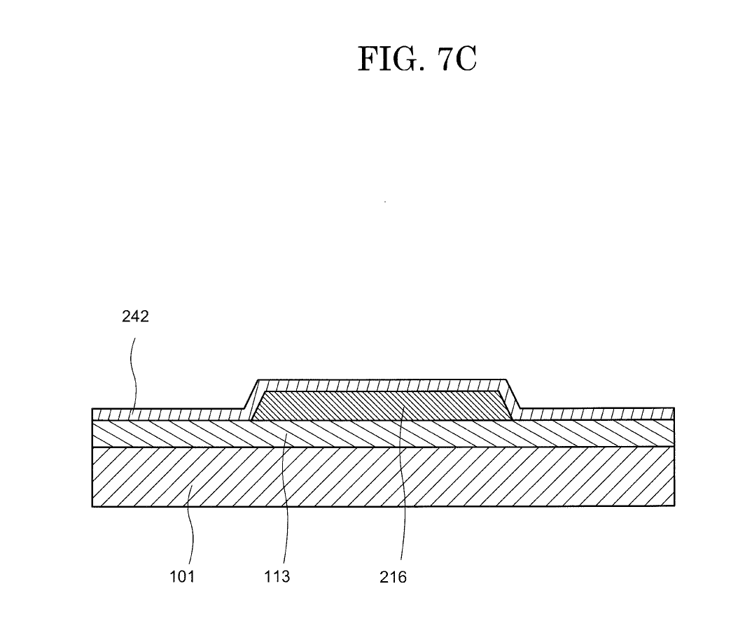

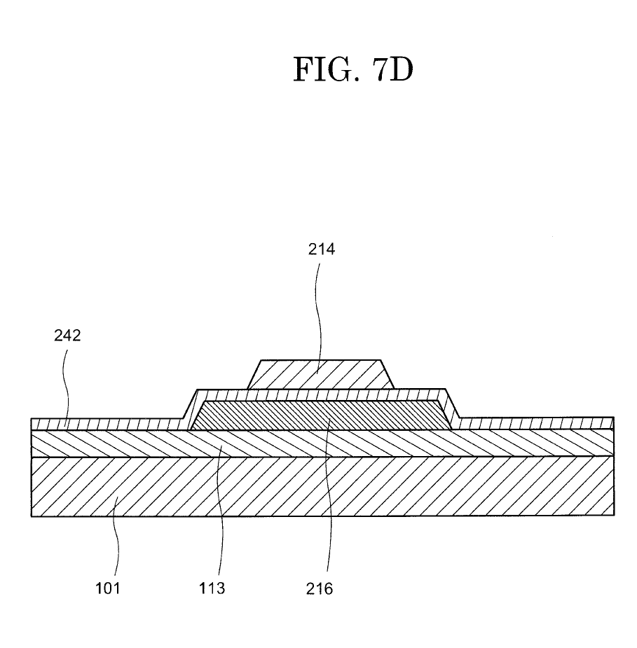

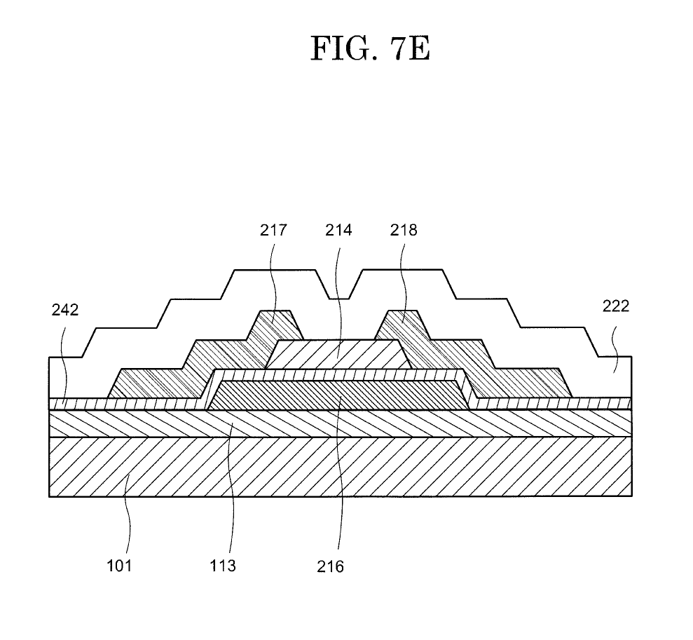

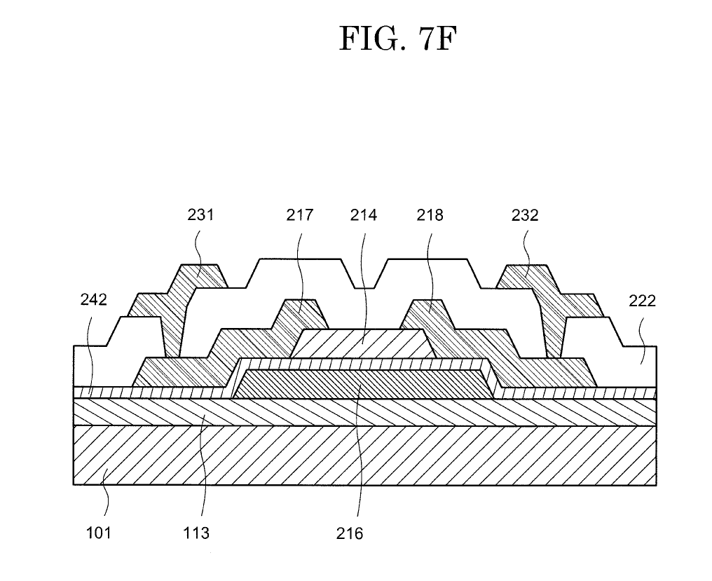

Next, a method of manufacturing the semiconductor device 200 according to the present embodiment is explained while referring to FIG. 7A to FIG. 7F.

First, as shown in FIG. 7A, an insulating layer 113 is formed above the substrate 101. The insulating layer 113 can be formed having a single layer structure or a stacked layer structure by using the materials described above by a CVD method, a sputtering method, or a lamination method and the like. The film thickness of the insulating layer 113 can be set to 50 nm or more and 1000 nm or less.

Next, as shown in FIG. 7B, a conducting layer 216 is formed. The conducting layer 216 is formed by forming a conducting film and subsequently patterning the conducting film into a desired shape. The conducting film can be formed in a single layer structure or a stacked layer structure by a sputtering method using the materials described above. In addition, the thickness of the conducting layer 216 is preferably 200 nm or more and 500 nm or less.

Next, an amorphous silicon film 241 is formed above the conducting layer 216. The amorphous silicon film 241 can be formed by a plasma CVD method using SiH₄ gas. In addition, the film thickness of the amorphous silicon film is preferably 100 nm or more and 300 nm or less.

Next, as shown in FIG. 7C, an insulating layer 242 is formed by performing an oxidation treatment on the amorphous silicon film 241. A plasma treatment or thermal treatment can be performed using as oxidation treatment. In the case where a plasma treatment is performed on the amorphous silicon film 241, it can be performed at an atmospheric pressure plasma or low pressure (vacuum) using a gas including oxygen such as O₂, N₂O or O₂/N₂. Conditions such as pressure, gas flow rate, power and treatment time, and the like may be set so that oxidation easily occurs according to the film quality and film thickness of the amorphous silicon film 141. Furthermore, in the case when a plasma treatment is performed, the plasma CVD device in which the amorphous silicon film 241 is formed can be continuously processed. Therefore, it is preferred since a separate device is not necessary which increases productivity.

In addition, in the case of performing a thermal treatment on the amorphous silicon film 241, it can be performed at an atmospheric pressure plasma or low pressure (vacuum) using a gas including oxygen such as O₂, N₂O or O₂/N₂. Conditions such as the pressure, the gas flow rate, the heating temperature and the treatment time and the like may be set so that oxidization easily occurs according to the film quality and film thickness of the amorphous silicon film 241. Furthermore, the heating temperature is preferably set appropriately in consideration of the heat resistance of the conducting layer 216.

In addition, a gate insulating film may be formed by further forming an insulating layer above the insulating layer 242. For example, SiNx and SiOx may be formed in this order above the insulating layer 242. In this case, the insulating layer 242, SiNx, and SiOx function as a gate insulating film. Furthermore, the film in contact with the oxide semiconductor layer 214 is preferably SiOx.

Next, as shown in FIG. 7D, the oxide semiconductor layer 214 is formed above the insulating layer 242. The oxide semiconductor layer 214 is formed by forming an oxide semiconductor film, and subsequently processing the oxide semiconductor film into a desired shape by patterning. It is preferable to form the oxide semiconductor film with a thickness of 30 nm or more and 100 nm or less by a sputtering method for example.

Furthermore, a plasma treatment may be performed on the oxide semiconductor layer 214. The plasma treatment can be carried out at atmospheric pressure plasma or low pressure (vacuum) using O₂ gas or N₂O gas. By performing a plasma treatment on the oxide semiconductor layer 214, it is possible to compensate for the oxygen defects in the oxide semiconductor layer 214. In this way, it is possible to improve the characteristics of the transistor and the reliability of the transistor.

Next, as shown in FIG. 7E, a conducting layer 217 and a conducting layer 218 are formed above the oxide semiconductor layer 214. The conducting layer 217 and the conducting layer 218 are formed by forming a conducting film above the oxide semiconductor layer 214 and processing the conductive film by patterning into a desired shape. The conducting film can be formed having a single layer structure or a stacked layer structure by a sputtering method using the materials described above. It is preferred to form Ti, Al, and Ti in this order in the case of forming the conducting layer 217 and the conducting layer 218 with a stacked layer structure. In addition, the thickness of the conducting layer 217 and the conducting layer 218 can be set to 300 nm or more and 800 nm or less. Furthermore, when forming the conducting layer 217 and the conducting layer 218, a part of the oxide semiconductor layer 214 may be removed.

Furthermore, although an example in which the conducting layer 217 and the conducting layer 218 are formed after forming the oxide semiconductor layer 214 is explained in the present embodiment, the present invention is not limited to this example. Although not shown, the conducting layer 217 and the conducting layer 218 may also be formed before forming the oxide semiconductor layer 214.

Next, an insulating layer 222 is formed above the oxide semiconductor layer 214, the conducting layer 217 and the conducting layer 218. The insulating layer 222 can be formed having a single layer structure or a stacked layer structure by using the materials described above or by an organic insulating material such as a polyimide resin, an acrylic resin, an epoxy resin, a silicone resin, a fluorine resin, a siloxane resin and the like by a CVD method or a sputtering method. In the case of forming the insulating layer 222 with a stacked structure, SiOx, SiNx, and SiOx are preferably formed in this order above the conducting layer 217 and the conducting layer 218. In addition, the thickness of the insulating layer 222 can be set to 300 nm or more and 600 nm or less.

Next, as shown in FIG. 7F, a plurality of openings are formed in the insulating layer 222 and the conducting layer 217 and the conducting layer 218 are exposed. Following this, a conducting layer 231 and a conducting layer 232 which are connected to the conducting layer 217 and the conducting layer 218 are formed. The conducting layer 231 and the conducting layer 232 are formed by forming a conducting film above the insulating layer 222 and patterning the conductive film into a desired shape. The conductive film can be formed with a single layer structure or a stacked structure by a sputtering method using the materials described above. In addition, the thickness of the conducting layer 231 and the conducting layer 232 can be set to 300 nm or more and 800 nm or less.

The semiconductor device 200 can be manufactured by the processes described above. According to the method for manufacturing the semiconductor device according to the present embodiment, the insulating layer 242 with a reduced hydrogen concentration can be formed by forming the amorphous silicon film 241 above the conducting layer 216 and performing an oxidation treatment. By forming the oxide semiconductor layer 214 above the insulating layer 242 having a reduced hydrogen concentration, it is possible to reduce hydrogen which causes carriers to be generated in the oxide semiconductor layer 214. In this way, since it is possible to suppress a shift of the threshold voltage of the transistor, it is possible to improve the reliability of the semiconductor device using the transistor.

### Modified Example 1

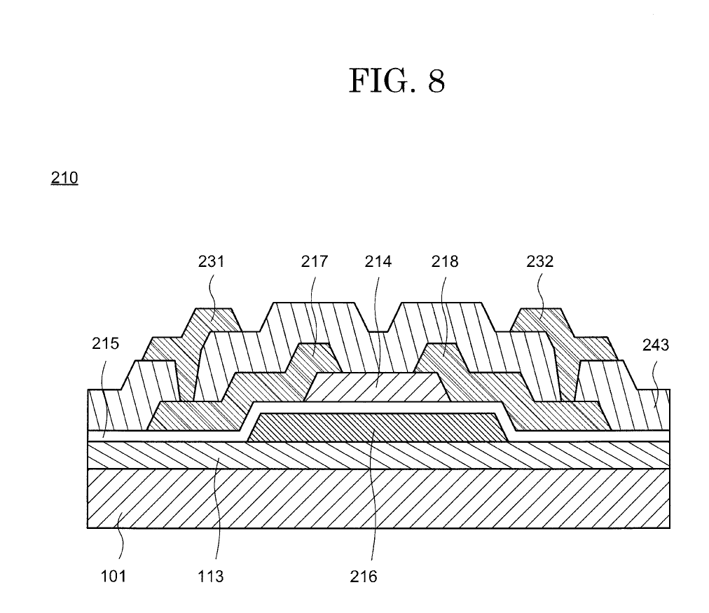

Next, a semiconductor device having a partly different structure from the semiconductor device shown in FIG. 6 is explained while referring to FIG. 8 to FIG. 10.

In the semiconductor device 210 shown in FIG. 8, the oxide semiconductor layer 214 is arranged above the insulating layer 215, and the conducting layer 217 and the conducting layer 218 are arranged above the oxide semiconductor layer 214. In addition, an insulating layer with a reduced hydrogen concentration is used for the insulating layer 243 which is in contact with the oxide semiconductor layer 214. The insulating layer 243 functions as a protective film. It is possible to form the insulating layer 243 by oxidizing an amorphous silicon film. Since the other structures are similar to the semiconductor device 200 shown in FIG. 6, a detailed explanation is omitted.

It is possible to perform a plasma treatment or thermal treatment as the oxidation treatment of the amorphous silicon film. In the case of a plasma treatment, it can be carried out at an atmospheric pressure plasma or low pressure (vacuum) using a gas including oxygen such as O₂, N₂O or O₂/N₂. It is possible to set conditions such as pressure, gas flow rate, power and processing time and the like so oxidation easily occurs according to the film quality and film thickness of the amorphous silicon film.

In addition, in the case when a thermal treatment is performed on the amorphous silicon film, it can be performed at an atmospheric pressure plasma or low pressure (vacuum) by using a gas including oxygen such as O₂, N₂O or O₂/N₂. It is possible to set conditions such as pressure, the gas flow rate, the heating temperature and the treatment time and the like so that oxidization easily occurs according to the film quality and film thickness of the amorphous silicon film. Furthermore, the heating temperature is preferably 450° C. or lower considering the heat resistance of the oxide semiconductor layer 114 and the heat resistance of the conducting layer 216, the conducting layer 217 and the conducting layer 218.

In the semiconductor device 210 shown in FIG. 8, a film with a reduced hydrogen concentration is used as the insulating layer 243 which is in contact with the oxide semiconductor layer 214. In this way, it is possible to suppress hydrogen which causes generation of carriers in the oxide semiconductor layer 214 from entering into the oxide semiconductor layer 214. Therefore, it is possible to suppress a shift of the threshold voltage of the transistor and improve the reliability of the semiconductor device using the transistor.

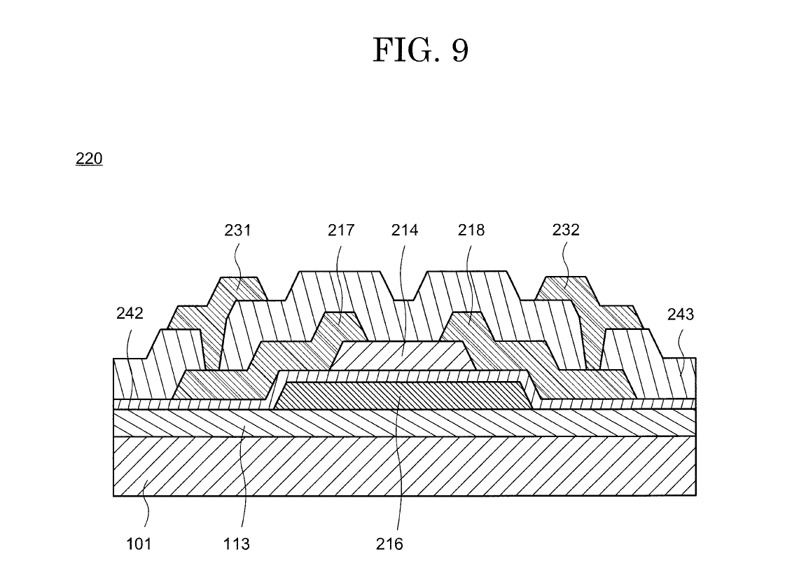

In the semiconductor device 220 shown in FIG. 9, an insulating layer with a reduced hydrogen concentration is used for the insulating layer 242 and the insulating layer 243 which are in contact with the oxide semiconductor layer 214. Each of the insulating layer 242 and the insulating layer 243 can be formed by oxidizing an amorphous silicon film. Since the other structures are similar to the semiconductor device 200 shown in FIG. 6, a detailed explanation is omitted.

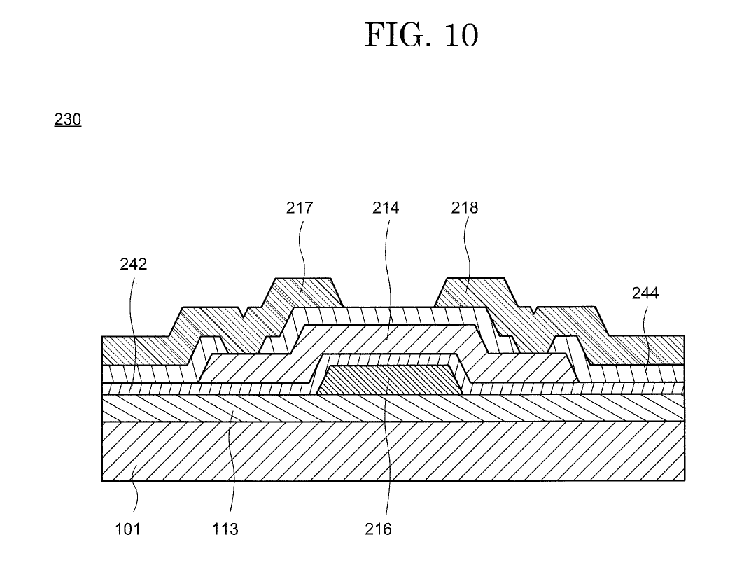

In the semiconductor device 230 shown in FIG. 10, the oxide semiconductor layer 214 is arranged above the insulating layer 242, and the insulating layer 244 is arranged above the oxide semiconductor layer 214. In addition, a plurality of openings part is arranged in the insulating layer 244 through which the oxide semiconductor layer 214 is exposed. The conducting layer 217 and the conducting layer 218 are connected to the oxide semiconductor layer 214 in the opening part. It is preferred to arrange the insulating layer 244 in contact with the oxide semiconductor layer 214 since the channel of a transistor can be protected.

Since the method of forming the insulating layer 242 and the insulating layer 244 is the same as the method explained in FIG. 6 to FIG. 8, a detailed explanation is omitted. In the semiconductor device 230 shown in FIG. 10, one of the insulating layer 242 and the insulating layer 244 is formed of a silicon oxide film formed by an oxidation treatment on an amorphous silicon film, and the other may be used as an insulating layer of another material.

In the semiconductor device 220 and the semiconductor device 230 described in the present embodiment, an insulating layer with a reduced hydrogen concentration is used for the insulating layer 242 and the insulating layer 244 which are in contact with the oxide semiconductor layer 214. In this way, it is possible to further suppress hydrogen which causes carriers to be generated in the oxide semiconductor layer 214 from entering penetrate into the oxide semiconductor layer 214 compared with the semiconductor device shown in FIG. 6 and FIG. 8. Therefore, since it is possible to suppress a shift of the threshold voltage of the transistor, it is possible to improve the reliability of the semiconductor device using the transistor.

### Modified Example 2

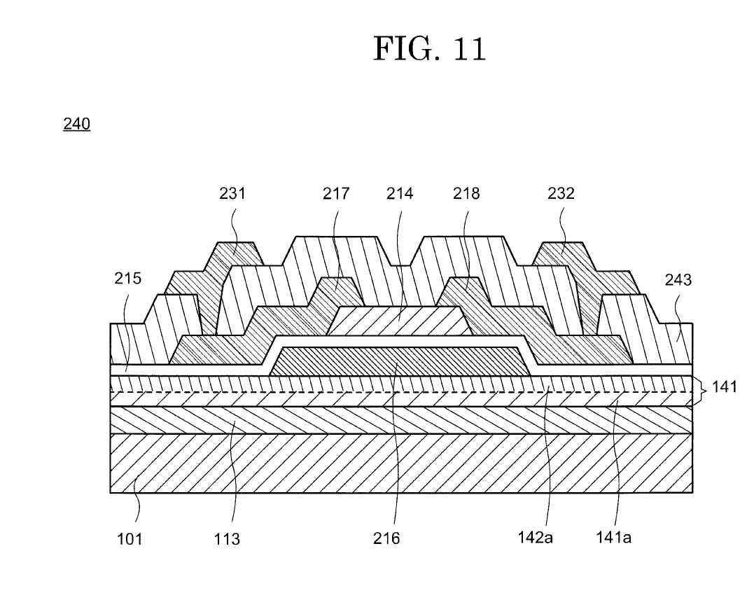

Next, a semiconductor device having a partly different structure from the semiconductor device shown in FIG. 8 is explained while referring to FIG. 11.

In the semiconductor device 240 shown in FIG. 11, an amorphous silicon film 141 is arranged above the insulating layer 113 the same as the semiconductor device 170 shown in FIG. 5. In addition, as shown in FIG. 11, a part of the amorphous silicon film 141 is oxidized. That is, the side in contact with the insulating layer 113 remains amorphous silicon and the side in contact with the conducting layer 216 is silicon oxide. Since the boundary between the amorphous silicon 141a and the oxidized region 142a is sometimes unclear, in FIG. 11 these boundaries are shown by dotted lines. Since the other structures are similar to the semiconductor device 200 shown in FIG. 6, a detailed explanation is omitted.

By performing an oxidation treatment on a part of the amorphous silicon film 141, the oxidized region 142a with a reduced hydrogen concentration is reduced can be formed in the region in contact with the oxide semiconductor layer 114. In addition, in the amorphous silicon film 141, the amorphous silicon 141a in contact with the insulating layer 113 has a lower oxygen concentration than the oxidized region 142a in contact with the oxide semiconductor layer 114. In addition, not all of the amorphous silicon film 141 is oxidized but a part of the amorphous silicon 141a remains in a region in contact with the insulating layer 113. Since it is possible to release an electric charge by the amorphous silicon 141a, it is possible to prevent static electricity breakage due to electrostatic discharge (ESD).

In addition, similar to the other semiconductor devices, since it is possible to suppress a shift of the threshold voltage of the transistor and deterioration of transistor characteristics, it is possible to improve the reliability of the semiconductor device using the transistor.

The film thickness of the amorphous silicon film 141 can be set to 60 nm or more and 250 nm or less. Within this range, the thickness of the amorphous silicon 141a is preferably 5 nm or more and 20 nm or less.

In the semiconductor device 240 shown in FIG. 11, it is possible to use an insulating layer 242 formed by oxidizing an amorphous silicon film instead of the insulating layer 215 which functions as a gate insulating film.

### Third Embodiment

In the present embodiment, an example is shown in which the structure of the semiconductor device described in the first embodiment and the second embodiment is applied to a display device.

### <Structure of Display Device>

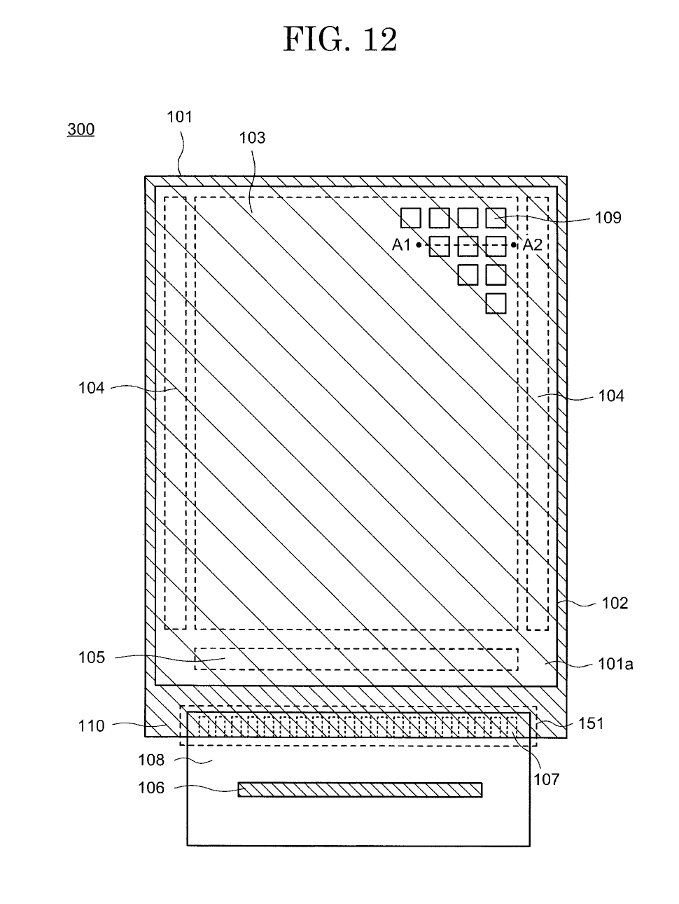

FIG. 12 is a schematic view showing a structure of a display device 300 according to one embodiment of the present invention, and shows a schematic structure in the case when the display device 300 is viewed in a planar view. In the present specification, a state in which the display device 300 is viewed from a direction perpendicular to the screen (display area) is called a “planar view”.

As shown in FIG. 12, the display device 300 includes a display region 103, a scanning line drive circuit 104, a data line drive circuit 105 and a driver IC 106 formed on an insulating surface. The driver IC 106 functions as a control part which provides a signal to the scanning line drive circuit 104 and the data line drive circuit 105. The data line drive circuit 105 may be incorporated within the driver IC 106. In addition, although the driver IC 106 is arranged externally above a chip on plastic 108 (COF), it may also be arranged above the substrate 101. The COF 108 is connected to a terminal 107 arranged in a periphery area 110.

Here, the insulating surface is the surface of the substrate 101. The substrate 101 supports each layer forming a transistor or light emitting element and the like arranged on the surface of the substrate. In the present embodiment, a foldable substrate is used as the substrate 101. An organic resin material such as polyimide, acrylic, epoxy, polyethylene terephthalate or the like can be used as the substrate 101.

A plurality of pixels 109 are arranged in a matrix in the display region 103 shown in FIG. 12. Each pixel 109 includes a liquid crystal element or a light emitting element as a display element. In the present embodiment, a case where a light emitting element is used is explained. The light emitting element includes a pixel electrode (anode), an organic layer (light emitting part) including a light emitting layer stacked above the pixel electrode, and a counter electrode (cathode). A data signal corresponding to image data is provided to each pixel 109 from the data line drive circuit 105. According to these data signals, a transistor electrically connected to a pixel electrode arranged in each pixel 109 is driven and screen display according to the image data is possible.

Here, the transistors shown in the first embodiment and the second embodiment can be used for the display region 103, the scanning line drive circuit 104 and the data line drive circuit 105. In the present embodiment, a case in which the transistor shown in FIG. 1 is used as the transistor 180 is shown.

### <Structure of a Pixel>

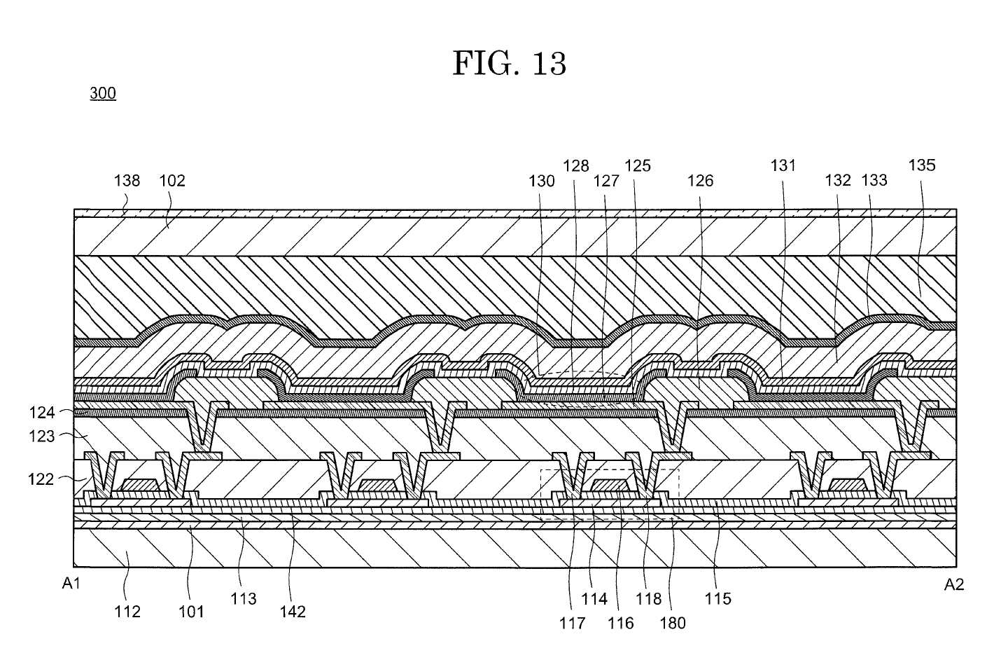

FIG. 13 is a diagram showing an example of a structure of a pixel in the display device 300 of the first embodiment. Specifically, the diagram shows the structure of a cross section cut along the line A1-A2 of the display region 103 shown in FIG. 12. A cross section of three display elements as a part of the display region 103 is shown in FIG. 13. Although three display elements are exemplified in FIG. 13, in reality, in the display region 103, several million display elements or more are arranged in a matrix corresponding to the pixels.

As shown in FIG. 13, the display device 300 includes a substrate 101, a protective film 112 and a protective film 102. A glass substrate, a quartz substrate, a flexible substrate (polyimide, polyethylene terephthalate, polyethylene naphthalate, triacetyl cellulose, cyclic olefin copolymer, cycloolefin polymer, or other resin substrate having flexibility) can be used as the substrate 101, the protective film 112 and the protective film 102. In the case when it is not necessary for the substrate 101, the protective film 112 and the protective film 102 to have translucency, it is also possible to use a metal substrate, a ceramic substrate or a semiconductor substrate. In the present embodiment, a case where polyimide is used as the substrate 101 and polyethylene terephthalate is used as the protective film 112 and the protective film 102 is explained.

An insulating layer 113 is arranged above the substrate 101. The insulating layer 113 may be appropriately determined considering adhesion to the substrate 101 and barrier properties against the transistor 180 described herein.

An insulating layer 142 is arranged above the insulating layer 113. The insulating layer 142 is an insulating layer in which the hydrogen concentration is reduced as described in the previous embodiment.

A transistor 180 is arranged above the insulating layer 142. The structure of the transistor 180 may be a top gate type or a bottom gate type. In the present embodiment, the transistor 180 includes the oxide semiconductor layer 114 arranged above the insulating layer 142, the insulating layer 115 covering the oxide semiconductor layer 114, and the conducting layer 116 arranged above the insulating layer 115. In addition, above the transistor 180, an insulating layer 122 which covers the conducting layer 116, and a conducting layer 117 and a conducting layer 118 which are respectively connected to the oxide semiconductor layer 114 are arranged above the insulating layer 122.

Furthermore, although not shown in FIG. 13, it is possible to arrange a first wiring formed of the same metal material as the metal material forming the conducting layer 116 in the same layer as the conducting layer 116. The first wiring can be arranged, for example, as a scanning line or the like driven by the scanning line drive circuit 104. Although not shown in FIG. 13, a second wiring extending in a direction intersecting the first wiring can be arranged in the same layer as the conducting layer 117 and the conducting layer 118. The second wiring can be arranged, for example, as a data line or the like driven by the data line drive circuit 105.

A planarization film 123 is arranged above the transistor 180. The planarization film 123 is formed including an organic resin material. For example, known organic resin materials such as polyimide, polyamide, acrylic, epoxy and the like can be used as the organic resin material. These materials are can form a film using a solution coating method and have a feature in which a flattening effect is high. Although not specifically shown in the diagram, the planarization film 123 is not limited to a single layer structure and may include a stacked layer structure of a layer containing an organic resin material and an inorganic insulating layer.

The planarization film 123 has a contact hole exposing a part of the conducting layer 118. The contact hole is an opening part for electrically connecting the pixel electrode 125 and the conducting layer 118 described herein. Therefore, the contact hole is arranged so as to overlap a part of the conducting layer 118. The conducting layer 118 is exposed at the bottom surface of the contact hole.

A protective film 124 is arranged above the flattening film 123. The protective film 124 overlaps the contact hole formed in the planarization film 123. The protective film 124 is preferred to have a barrier function against moisture and oxygen, and is formed for example, using an inorganic insulating material such as a silicon nitride film or aluminum oxide.

A pixel electrode 125 is arranged above the protective film 124. The pixel electrode 125 overlaps the contact hole of the planarization film 123 and the protection film 124 and is electrically connected to the conducting layer 117 or the conducting layer 118 exposed at the bottom surface of the contact hole. In the display device 300 of the present embodiment, the pixel electrode 125 functions as an anode forming the light emitting element 130. The pixel electrode 125 has a different structure depending on whether it is a top emission type or a bottom emission type. For example, in the case of a top emission type, it is preferred to use a metal film having high reflectance as the pixel electrode 125 or a stacked layer structure of a transparent conductive film with a high work function such as an indium oxide type transparent conductive layer (for example, ITO) or a zinc oxide type transparent conductive layer (for example, IZO, ZnO) and a metal film. On the other hand, in the case of a bottom emission type, the transparent conductive layer described above is used as the pixel electrode 125. In the present embodiment, a top emission type organic EL display device is explained as an example. The end part of the pixel electrode 125 is covered by an insulating layer 126 described herein.

An insulating layer 126 formed of an organic resin material is arranged above the pixel electrode 125. A known resin material such as polyimide, polyamide, acrylic, epoxy or siloxane can be used as the organic resin material. The insulating layer 126 has an opening part in a part of the top of the pixel electrode 125. The insulating layer 126 is arranged to cover the end part (edge part) of the pixel electrode 125 between adjacent pixel electrodes 125, and functions as a member that separates adjacent pixel electrodes 125. As a result, the insulating layer 126 is also generally called a “partition wall” or “bank”. A part of the pixel electrode 125 exposed from the insulating layer 126 serves as a light emitting region of the light emitting element 130. It is preferred that the inner wall of the opening part of the insulating layer 126 is formed in a tapered shape in advance. In this way, it is possible to reduce coverage defects at the end part of the pixel electrode 125 at the time of forming a light emitting layer described herein. The insulating layer 126 may not only cover the end part of the pixel electrode 125 but also function as a filling material filling a concave part cause by the contact hole of the planarization film 123 and the protective film 124.

An organic layer 127 is arranged above the pixel electrode 125. The organic layer 127 includes at least a light emitting layer formed of an organic material and functions as a light emitting part of the light emitting element 130. In addition to the light emitting layer, the organic layer 127 may include various charge transport layers such as an electron injection layer, an electron transport layer, a hole injection layer and a hole transport layer. The organic layer 127 is arranged to cover a light emitting region, that is, to cover an opening part of the insulating layer 126 and an opening part of the insulating layer 126 in the light emitting region.

Furthermore, in the present embodiment, a structure is provided that displays each color of RGB by forming a light emitting layer which emits light of a desired color in the organic layer 127 and forming the organic layer 127 having different light emitting layers above each pixel electrode 125. That is, in the present embodiment, the light emitting layer of the organic layer 127 is discontinuous between adjacent pixel electrodes 125. In addition, various charge transport layers are continuous between adjacent pixel electrodes 125. A known structure or a known material can be used for the organic layer 127, and is not particularly limited to the structure of the present embodiment. In addition, the organic layer 127 has a light emitting layer which emits white light, and each color of RGB may be displayed through a color filter. In this case, the organic layer 127 may also be arranged above the insulating layer 126.

A counter electrode 128 is arranged above the organic layer 127 and the insulating layer 126. The counter electrode 128 functions as a cathode which forms the light emitting element 130. Since the display device 300 of the present embodiment is a top emission type, a transparent electrode is used as the counter electrode 128. An MgAg thin film or a transparent conducting layer (ITO or IZO) is used as the thin film forming the transparent electrode. The counter electrode 128 is also arranged above the insulating layer 126 across each pixel 109. The counter electrode 128 is electrically connected to an external terminal via a lower conducting layer in a periphery region near the end of the display region 103. As described above, in the present embodiment, the light emitting element 130 is formed by a part (anode) of the pixel electrode 125, the organic layer 127 (light emitting part) and the counter electrode 128 (cathode) exposed from the insulating layer 126.

As shown in FIG. 13, a first inorganic insulating layer 131, an organic insulating layer 132, and a second inorganic insulating layer 133 are arranged above the display region 103. The first inorganic insulating layer 131, the organic insulating layer 132, and the second inorganic insulating layer 133 function as a sealing film for preventing moisture and oxygen from entering the light emitting element 130. By arranging the sealing film above the display region 103, moisture and oxygen can be prevented from entering the light emitting element 130, and it is possible to improve the reliability of the display device. A film of silicon nitride (SixNy), silicon oxynitride (SiOxNy), silicon nitride oxide (SiNxOy), aluminum oxide (AlxOy), aluminum nitride (AlxNy), aluminum nitride (AlxOyNz), aluminum nitride oxide (AlxNyOz) or the like can be used as the first inorganic insulating layer 131 and the second inorganic insulating layer 133 (x, y and z are arbitrary). In addition, it is possible to use a polyimide resin, an acrylic resin, an epoxy resin, a silicone resin, a fluororesin or a siloxane resin or the like as the organic insulating layer 132.

An adhesive material 135 is arranged above the second inorganic insulating layer 133. For example, an acrylic type, rubber type, silicone type or urethane type adhesive material can be used as the adhesive material 135. In addition, the adhesive material 135 may include moisture absorbing substances such as calcium and zeolite. By including moisture absorbing substance in the adhesive material 135, even when moisture enters into the display device 300, it is possible to delay the arrival of moisture to the light emitting element 130. A spacer may also be arranged above the adhesive material 135 to secure a gap between the substrate 101 and the protective film 102. Such a spacer may be mixed with the adhesive material 135 or may be formed of a resin or the like above the substrate 101.

For example, an overcoat layer may be arranged also for planarization in the protective film 102. In the case when the organic layer 127 emits white light, a color filter corresponding to each color of RGB and a black matrix arranged between the color filters are formed on a main surface (surface facing the substrate 101) may be arranged in the protective film 102. When a color filter is not formed on the side of the protective film 102, for example, a color filter may be directly formed on the sealing film, and the adhesive 135 may be formed thereupon. In addition, a polarization plate 138 is arranged on the rear surface (display surface side) of the protective film 102.

In the transistor explained in the previous embodiment, since an insulating layer with a reduced hydrogen concentration is used in contact with the oxide semiconductor layer 114, it is possible to suppress hydrogen which causes carriers to be generated in the oxide semiconductor layer 114 from entering. In this way, since it is possible to prevent a shift in threshold voltage of a transistor and prevent deterioration of transistor characteristics, it is possible to improve the reliability of the transistor. By manufacturing the display device using the transistor, it is possible to obtain a highly reliable display device. In addition, in each light-emitting element, variations in transistor characteristics can be suppressed and it is possible to improve the display quality of the display device.

Although an example in which a transistor including an oxide semiconductor layer is applied to a pixel in the display region 103 was explained in the present embodiment. One embodiment of the present invention is not limited to this example. The present embodiment can also be applied to transistors included in the scanning line drive circuit 104 and the data line drive circuit 105.

In addition, in the case where the display device 300 is a bendable display device, the substrate 101 is formed above support substrate (not shown) and the second inorganic insulating layer 133 which functions as a sealing film is formed. Next, after bonding the protective film 102 via the adhesive material 135, the support substrate is peeled off by irradiating laser light from the rear side of the support substrate. Following this, the polarization plate 138 is bonded to the protective film 102, and the protective film 112 is bonded to the substrate 101, whereby it is possible to manufacture a bendable display device.

Although a case where the present invention is applied to an organic EL display device using a light emitting element was explained as a display device in the present embodiment, the present invention is not limited to this example. The present embodiment may also be applied as a display device to a liquid crystal display device.

### Fourth Embodiment

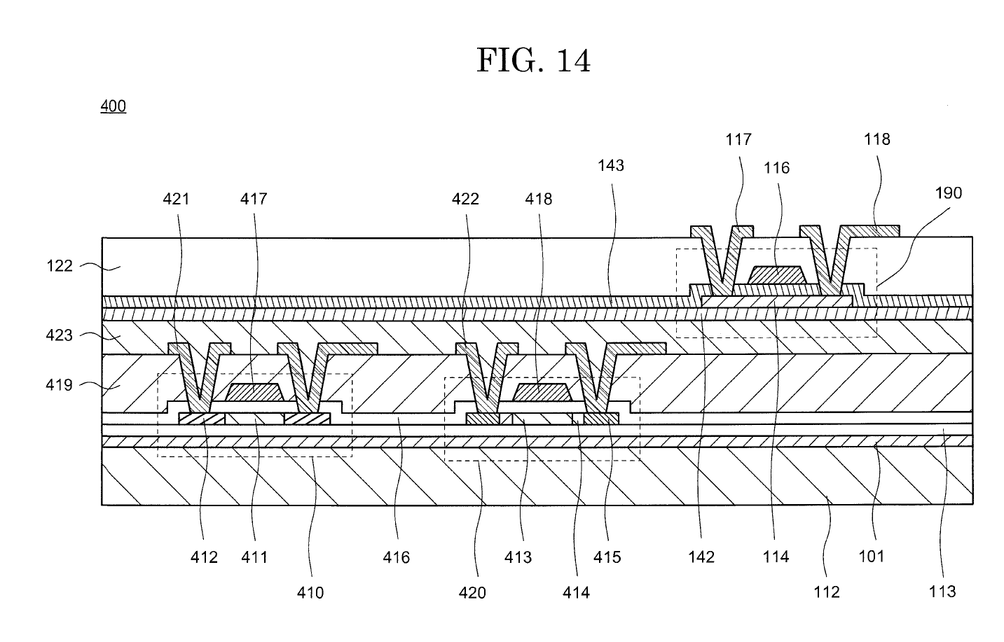

In the present embodiment, a structure of a semiconductor device according to another embodiment of the present invention is explained while referring to FIG. 14. In the present embodiment, a semiconductor device arranged with a transistor formed by an oxide semiconductor above a transistor formed by polysilicon is explained. Furthermore, explanations of structures the same as those of the other embodiments are omitted as appropriate.

The semiconductor device 400 shown in FIG. 14 includes a transistor 410, a transistor 420 and a transistor 190. The transistor 410 and the transistor 420 are arranged above the protective film 112 with the substrate 101 interposed therebetween. Polysilicon is used as a semiconductor layer in the transistor 410 and the transistor 420, and an oxide semiconductor is used as the semiconductor layer of the transistor 190.

A transistor using an oxide semiconductor can be manufactured without affecting the characteristics of the transistor 410 and the transistor 420 formed from polysilicon since the process temperature is as low as around 450° C. In this way, it is possible to form the transistor 190 formed from an oxide semiconductor above the transistor 410 and the transistor 420 which are formed from polysilicon.

The transistor 410 is a p-type transistor. The transistor 410 includes a polysilicon semiconductor layer, a gate insulating layer 416 and a gate electrode 417. A channel 411 and an impurity region 412 including p-type impurities are included in the semiconductor layer of the transistor 410. In addition, the transistor 420 is an n-type transistor. The transistor 420 includes a polysilicon semiconductor layer, a gate insulating layer 416 and a gate electrode 418. The semiconductor layer of the transistor 420 includes a channel 413, an impurity region 415 including n-type impurities and an impurity region 414 including n-type impurities at a concentration lower than that of the impurity region 415.

An insulating layer 419 is arranged above the transistor 410 and the transistor 420. In addition, a plurality of openings parts is arranged in the insulating layer 419. A source or drain electrode 421 and the impurity region 412 are connected in one opening part, a source or drain electrode 422 and the impurity region 415 are connected in the other opening part.

An insulating layer 423 is arranged above the insulating layer 419, the source or drain electrode 421, and the source or drain electrode 422.

An insulating layer 142 is arranged above the insulating layer 423. The insulating layer 142 is a film formed by oxidizing an amorphous silicon film and is an insulating layer with a reduced hydrogen concentration. A transistor 190 using the oxide semiconductor layer 114 is arranged above the insulating layer 423.

The transistor 190 includes an oxide semiconductor layer 114, an insulating layer 143, and a conducting layer 116. The insulating layer 143 is a film formed by oxidizing an amorphous silicon film, and is an insulating layer with a reduced hydrogen concentration. By forming the insulating layer in contact with the oxide semiconductor layer 114 an insulating layer with a reduced hydrogen concentration, it is possible to suppress hydrogen from entering the oxide semiconductor layer 114. In this way, it is possible to prevent a shift in a threshold voltage of the transistor 190 and prevent deterioration in transistor characteristics.

In addition, an insulating layer 122 is arranged above the transistor 190, and the insulating layer 122 includes a plurality of opening parts. The conducting layer 117 and the conducting layer 118 and the oxide semiconductor layer 114 are connected in the opening part.

As described above, the semiconductor device according to the present embodiment is a highly reliable semiconductor device in which a threshold shift of a transistor and deterioration of transistor characteristics are suppressed.

The semiconductor device described in this embodiment can be applied to, for example, a display region or a drive circuit of a display device and the like.

Based on the display device explained using the embodiments and examples according to the present invention, the appropriate addition, deletion, or design change of elements or the addition, deletion, or condition change of a process by a person ordinarily skilled in the art is included in the scope of the present invention as long as they possess the concept of the present invention. In addition, each embodiment described above can be mutually combined within a scope that does not produce any technical contradiction.

In addition, even if other actions and effects different from the actions and effects brought about by the embodiments described above are obvious from the description of this specification, or those which can be easily predicted by a person skilled in the art, it is to be understood that such actions and effects are obviously provided by the present invention.

What is claimed is:

1. A manufacturing method of a semiconductor device, the method comprising:
forming an amorphous silicon film on an insulation surface;
forming a silicon oxide film using an oxidation treatment from the amorphous silicon film;
forming an oxide semiconductor layer above the silicon oxide film;
forming a gate insulating film above the oxide semiconductor layer; and
forming a gate electrode interposed by the gate insulating film above the oxide semiconductor layer.

2. The method according to claim 1, wherein the oxidation treatment is a plasma treatment using a gas containing oxygen.

3. The method according to claim 2, wherein O₂, N₂O or O₂/N₂ is used as the gas containing oxygen.

4. The method according to claim 1, wherein the oxidation treatment is a thermal oxidation using a gas containing oxygen.

5. The method according to claim 4, wherein O₂, N₂O or O₂/N₂ is used as the gas containing oxygen.

6. The method according to claim 4, wherein the thermal treatment is performed at a temperature of 100° C. or more and 450° C. or less.

7. A manufacturing method of a semiconductor device, the method comprising:
forming an amorphous silicon film on an insulation surface;
forming a first region in which a part of the amorphous silicon film is oxidized using an oxidation treatment from a part of the amorphous silicon film;
forming an oxide semiconductor layer above the first region;
forming a gate insulating film above the oxide semiconductor layer; and
forming a gate electrode interposed by the gate insulating film above the oxide semiconductor layer.

8. The method according to claim 7, wherein the oxidation treatment is a plasma treatment using a gas containing oxygen.

9. The method according to claim 8, wherein O₂, N₂O or O₂/N₂ is used as the gas containing oxygen.

10. The method according to claim 7, wherein the oxidation treatment is a thermal oxidation using a gas containing oxygen.

11. The method according to claim 10, wherein O₂, N₂O or O₂/N₂ is used as the gas containing oxygen.

12. The method according to claim 10, wherein the thermal treatment is performed at a temperature of 100° C. or more and 450° C. or less.

13. A semiconductor device comprising:
an insulating layer above a substrate;
an amorphous silicon film above the insulating layer;
an oxide semiconductor layer above the amorphous silicon film;
a gate insulating film above the oxide semiconductor layer; and
a gate electrode arranged interposed by the gate insulating film above the oxide semiconductor layer;
wherein
the amorphous silicon has a first region on a side in contact with the insulating layer and a second region on a side in contact with the oxide semiconductor layer,
an oxygen concentration of the first region is lower than an oxygen concentration of the second region.

14. The semiconductor device according to claim 13, wherein a film thickness of the amorphous silicon film is 60 nm or more and 250 nm or less.

15. The semiconductor device according to claim 13, wherein a thickness of the first region from a boundary with the insulating layer is 5 nm or more and 20 nm or less.
